(19) United States
(12) Patent Application Publication
(10) Pub. No.: US 2025/0149237 A1
(43) Pub. Date: May 8, 2025

(54) SYSTEM WITH ACHIEVED IMPEDANCE MATCHING

(71) Applicant: RichWave Technology Corp., Taipei City (TW)

(72) Inventors: Chia-Jung Yeh, Taipei City (TW); Chih-Sheng Chen, Taipei City (TW)

(73) Assignee: RichWave Technology Corp., Taipei City (TW)

(21) Appl. No.: 18/395,653

(22) Filed: Dec. 25, 2023

(51) Int. Cl. H01F 27/42; H01F 27/40; H01F 38/14

(52) U.S. Cl. CPC H01F 27/42; H01F 27/40; H01F 38/14

(57) ABSTRACT

A system includes a primary coil, a series combination having a first conducting wire and a first capacitor coupled in series, a second conducting wire, and a secondary coil. A first end of the series combination is coupled to a first end of the primary coil. A first end of the second conducting wire is coupled to the first end of the primary coil. A second end of the second conducting wire is coupled to the second end of the series combination. A first end of the secondary coil is coupled to an output end.

### TECHNICAL FIELD

The present invention is related to a system with impedance matching, and more particularly, to a conducting wire system with impedance matching.

### BACKGROUND

A transformer is a device capable of transferring electrical energy from one electrical circuit to another circuit using inductive coupling. Transformers are used to change voltage levels, adjust impedance and provide galvanic isolation between circuits. Transformers have become essential for the transmission, distribution, and utilization of alternating current electric power. For example, transformers are commonly used in a differential circuit for providing impedance matching.

A transformer usually includes two electrically isolated coils and operates on Faraday's principal of mutual induction. The transformer may be implemented on a semiconductor chip and coupled to the load of the system (such as an amplifier) via conducting wires (such as bonding) wires. However, the conducting wires generate extra inductive impedance, thereby increasing the demand of impedance matching in the system.

### SUMMARY

The present invention provides a system which includes a primary coil, a first series combination, a second conducting wire and a secondary coil. The primary coil includes a first end and a second end. The first series combination comprises a first conducting wire and a first capacitor coupled in series, wherein a first end of the first series combination is coupled to the first end of the primary coil. A first end of the second conducting wire is coupled to the first end of the primary coil, and a second end of the second conducting wire is coupled to a second end of the first series combination. The secondary coil includes a first end and a second end, wherein the first end of the secondary coil is coupled to an output end.

The present invention also provides a system which includes a primary coil, a first bonding wire, a first series combination, a second series combination, a fourth bonding wire and a secondary coil. The primary coil includes a first end and a second end. The first bonding wire includes a first end coupled to the first end of the primary coil. The first series combination comprises a second bonding wire and a first capacitor coupled in series, wherein a first end of the first series combination is coupled to the first end of the primary coil. The second series combination comprises a third bonding wire and a second capacitor coupled in series, wherein a first end of the second series combination is coupled to the second end of the primary coil, and a second end of the second series combination is coupled to a second end of the first bonding wire. The fourth bonding wire includes a first end coupled to the second end of the primary coil and a second end coupled to the second end of the first series combination. The secondary coil includes a first end and a second end, wherein the first end of the secondary coil is coupled to an output end.

The present invention also provides a system which includes a primary coil, a first trace, a first series combination, a second series combination, a fourth trace and a secondary coil. The primary coil includes a first end and a second end. The first trace includes a first end coupled to the first end of the primary coil. The first series combination comprises a second trace and a first capacitor coupled in series, wherein a first end of the first series combination is coupled to the first end of the primary coil. The second series combination comprises a third trace and a second capacitor coupled in series, wherein a first end of the second series combination is coupled to the second end of the primary coil, and a second end of the second series combination is coupled to a second end of the first trace. The fourth trace includes a first end coupled to the second end of the primary coil and a second end coupled to the second end of the first series combination. The secondary coil includes a first end and a second end, wherein the first end of the secondary coil is coupled to an output end.

### BRIEF DESCRIPTION OF THE DRAWINGS

FIG. 1 is a diagram illustrating a system according to an embodiment of the present invention.

FIG. 2 is a diagram illustrating a system according to another embodiment of the present invention.

FIG. 3A is a diagram illustrating a system according to another embodiment of the present invention.

FIG. 3B is a diagram illustrating a system according to another embodiment of the present invention.

FIG. 3C is a diagram illustrating a system according to another embodiment of the present invention.

FIG. 4A is a diagram illustrating a system according to another embodiment of the present invention.

FIG. 4B is a diagram illustrating a system according to another embodiment of the present invention.

FIG. 4C is a diagram illustrating a system according to another embodiment of the present invention.

FIG. 4D is a diagram illustrating a system according to another embodiment of the present invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

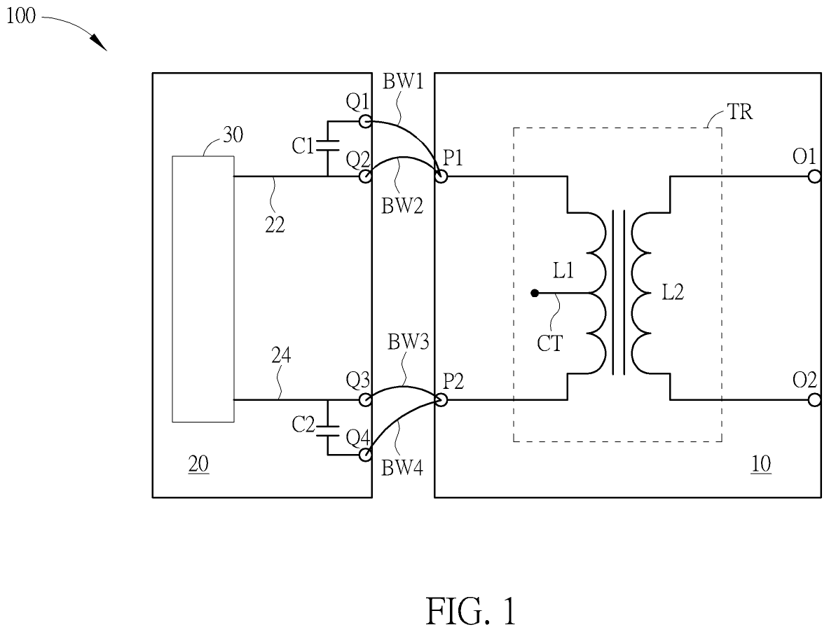

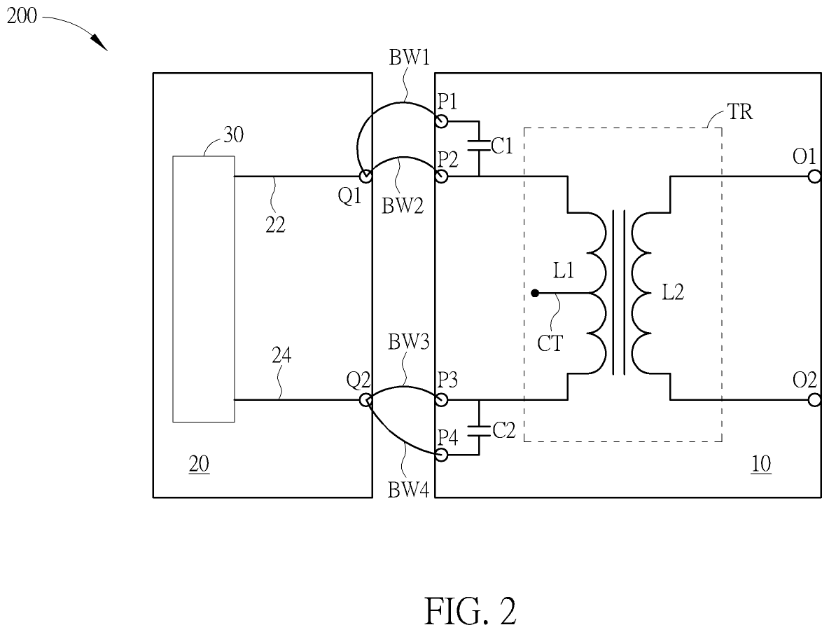

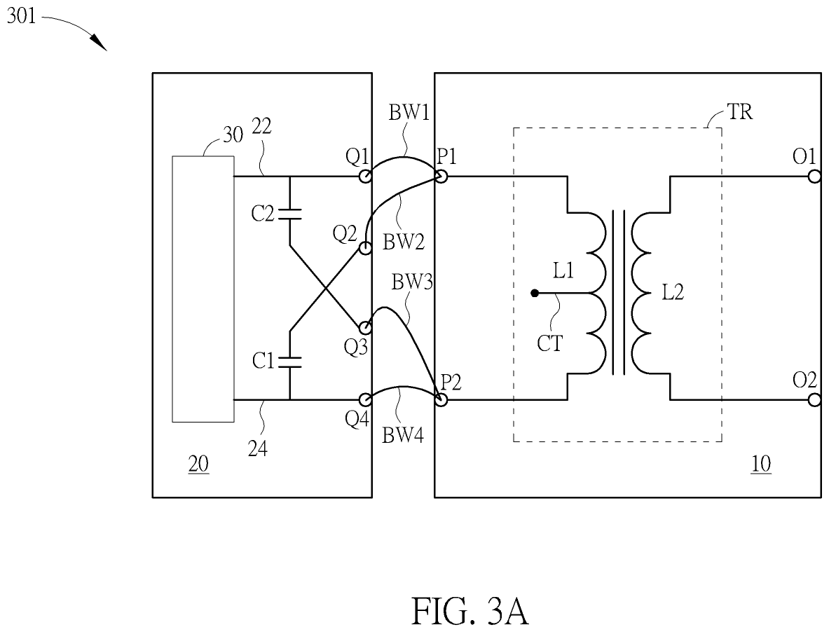

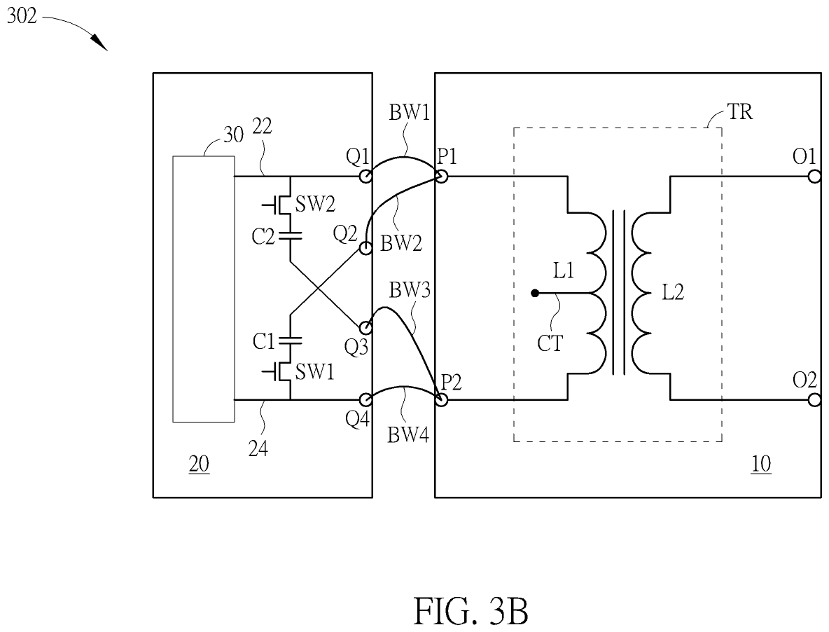

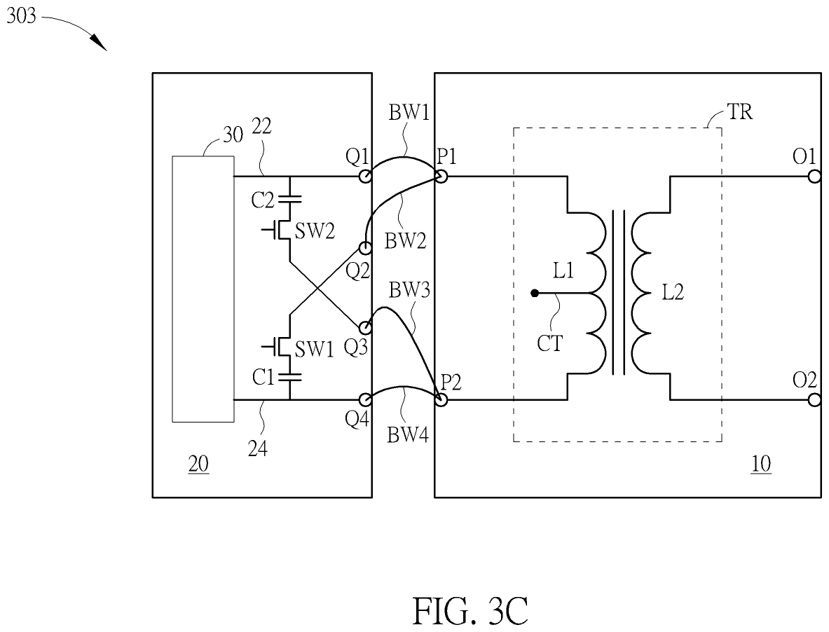

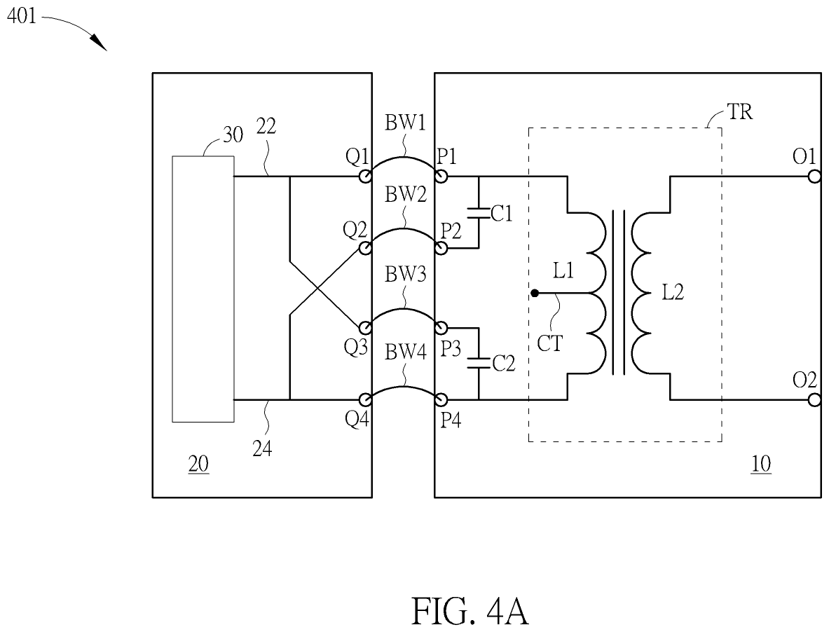

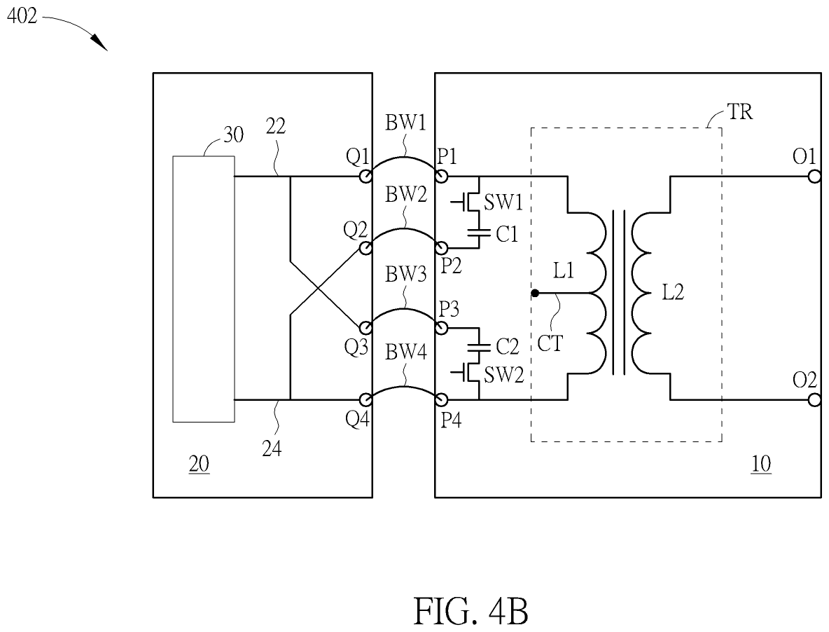

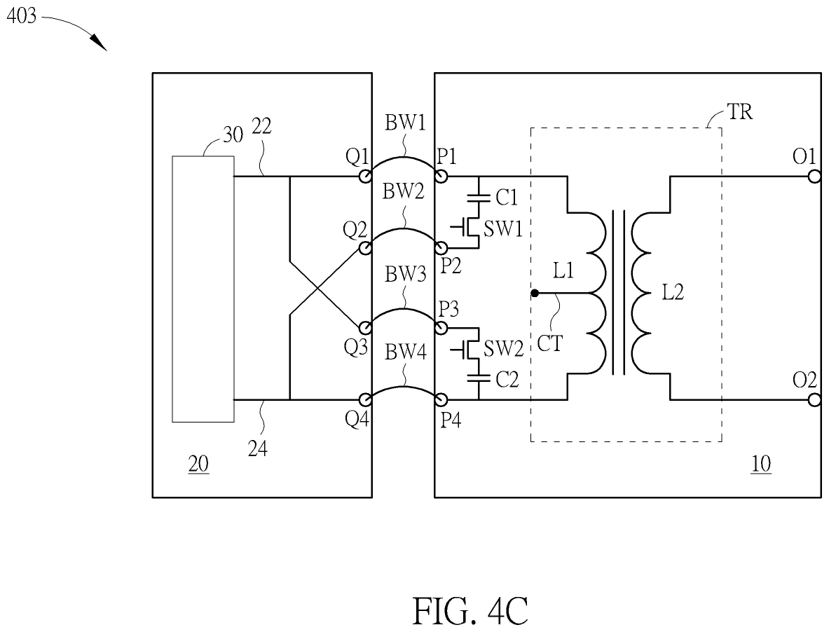

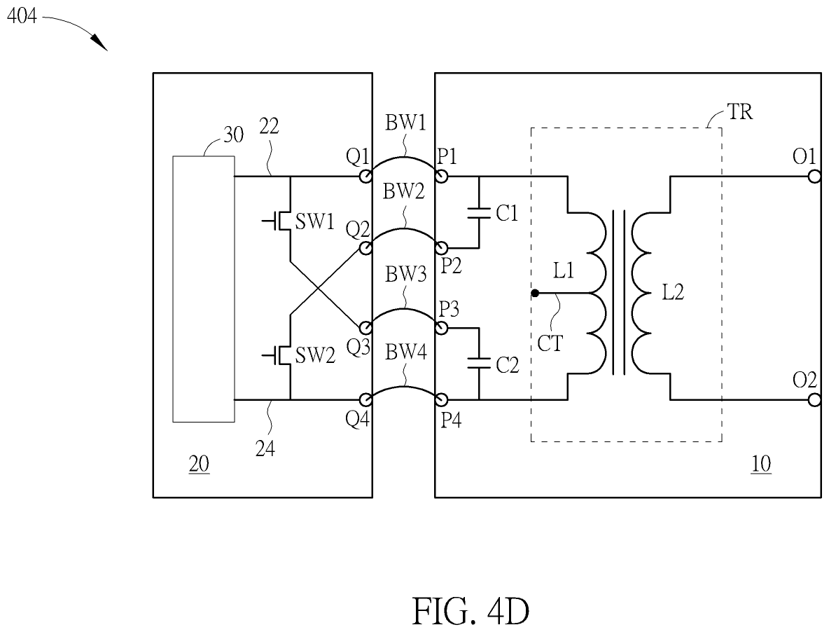

FIG. 1 is a diagram illustrating a system 100 according to an embodiment of the present invention. FIG. 2 is a diagram illustrating a system 200 according to another embodiment of the present invention. FIGS. 3A-3C are diagrams illustrating systems 301-303 according to other embodiments of the present invention. FIGS. 4A-4D are diagrams illustrating systems 401-404 according to other embodiments of the present invention.

As depicted in FIG. 1, the system 100 includes a primary coil L1, a secondary coil L2, a first series combination and a bonding wire BW2, wherein the first series combination includes a bonding wire BW1 and a capacitor C1 coupled in series. The first end of the first series combination is coupled to the first end of the primary coil L1, the first end of the bonding wire BW2 is also coupled to the first end of the primary coil L1, the second end of the bonding wire BW2 is coupled to the second end of the first series combination, and the first end of the secondary coil L2 is coupled to an output end O1. Regarding the arrangement of the bonding wire BW1 and the capacitor C1 in the first series combination, the first end of the bonding wire BW1 is coupled to the first end of the primary coil L1, the second end of the bonding wire BW1 is coupled to the first end of the capacitor C1, the second end of the capacitor C1 is coupled to the second end of the bonding wire BW2 in the embodiment depicted in FIG. 1. This way, the bonding wire BW1 and the capacitor C1 in the first series combination together generate capacitive impedance which reduces inductive impedance generated by the bonding wire BW2. In some embodiments, the capacitive impedance generated by the bonding wire BW1 and the capacitor C1 in the first series combination together may compensate the inductive impedance generated by the bonding wire BW2.

In some embodiments, the system 100 depicted in FIG. 1 may further include a bonding wire BW3 and a second series combination, wherein the second series combination includes a bonding wire BW4 and a capacitor C2 coupled in series. The first end of the bonding wire BW3 is coupled to the second end of the primary coil L1, the first end of the second series combination is coupled to the second end of the primary coil L1, and the second end of the second series combination is coupled to the second end of the bonding wire BW3. Regarding the arrangement of the bonding wire BW4 and the capacitor C2 in the second series combination, the first end of the bonding wire BW4 is coupled to the second end of the primary coil L1, the second end of the bonding wire BW4 is coupled to the first end of the capacitor C2, and the second end of the capacitor C2 is coupled to the second end of the bonding wire BW3 in the embodiment depicted in FIG. 1. This way, the bonding wire BW4 and the capacitor C2 in the second series combination together generate capacitive impedance which reduces inductive impedance generated by the bonding wire BW3. In some embodiments, the capacitive impedance generated by the bonding wire BW4 and the capacitor C2 in the second series combination together may compensate the inductive impedance generated by the bonding wire BW3.

In the present invention, the system 100 depicted in FIG. 1 includes a first chip 10 and a second chip 20. A transformer TR is disposed on the first chip 10 and includes the above-mentioned primary coil L1 and secondary coil L2. As depicted in FIG. 1, the primary coil L1 includes a center tap CT leading out from the center of the primary coil L1, wherein the center tap CT may be coupled to a power voltage (not shown in FIG. 1). The primary coil L1 and the secondary coil L2 are disposed near each other so as to induce mutual induction between the primary coil L1 and the secondary coil L2, thereby outputting induction current. Also, the bonding wires BW1, BW2, BW3 and BW4 are respectively wire-bonded between the first chip 10 and the second chip 20. Furthermore, in the system 100 depicted in FIG. 1, the first chip 10 may include two pads P1-P2 and the second chip 20 may include four pads Q1-Q4, wherein the first and second ends of the bonding wire BW1 are respectively connected to the pad P1 of the first chip 10 and the pad Q1 of the second chip 20, the first and second ends of the bonding wire BW2 are respectively connected to the pad P1 of the first chip 10 and the pad Q2 of the second chip 20, the first and second ends of the bonding wire BW3 are respectively connected to the pad P2 of the first chip 10 and the pad Q3 of the second chip 20, and the first and second ends of the bonding wire BW4 are respectively connected to the pad P2 of the first chip 10 and the pad Q4 of the second chip 20. In other words, the bonding wires BW1 and BW2 are connected to the first chip 10 via the shared pad P1, the bonding wires BW3 and BW4 are connected to the first chip 10 via the shared pad P2, and the bonding wires BW1-BW4 are respectively connected to the second chip 20 via dedicated pads Q1-Q4. In other embodiments, the bonding wires BW1 and BW2 may also be connected to the first chip 10 via two dedicated pads which are coupled to each other via a trace instead of using the pad P1 as a shared contact point. Similarly, the bonding wires BW3 and BW4 may be connected to the first chip 10 via two dedicated pads which are coupled to each other via a trace instead of using the pad P2 as a shared contact point.

In the system 100 depicted in FIG. 1, the first chip 10 further include two pads O1-O2 as its output ends O1-O2. The first end of the primary coil L1 is coupled to the first ends of the bonding wires BW1 and BW2 via the pad P1, the second end of the primary coil L1 is coupled to the first ends of the bonding wires BW3 and BW4 via the pad P2, the first end of the secondary coil L2 is coupled to the pad O1, and the second end of the secondary coil L2 is coupled to the pad O2. Also, in the embodiment depicted in FIG. 1, the first end of the capacitor C1 is coupled to the pad Q1 of the second chip 20 (i.e., the first end of the capacitor C1 may be coupled to the pad P1 of the first chip 10 via the bonding wire BW1), the second end of the capacitor C1 is coupled to the pad Q2 of the second chip 20 (i.e., the second end of the capacitor C1 may be coupled to the pad P1 of the first chip 10 via the bonding wire BW2), the first end of the capacitor C2 is coupled to the pad Q4 of the second chip 20 (i.e., the first end of the capacitor C2 may be coupled to the pad P2 of the first chip 10 via the bonding wire BW4), and the second end of the capacitor C2 is coupled to the pad Q3 of the second chip 20 (i.e., the second end of the capacitor C2 may be coupled to the pad P2 of the first chip 10 via the bonding wire BW3). In the second chip 20, the pad Q1 is coupled to the pad Q2 via the capacitor C1, and the pad Q3 is coupled to the pad Q4 via the capacitor C2.

In some embodiments, the system 100 depicted in FIG. 1 may be applied to a structure using differential signaling. Therefore, the system 100 may further include traces 22 and 24 which may be coupled to the load of the system 100. In the embodiment depicted in FIG. 1, the load of the system 100 is for example the amplifier 30, the first end of the trace 22 is coupled to the second end of the bonding wire BW1, the second end of the trace 22 is coupled to the amplifier 30, the first end of the trace 24 is coupled to the second end of the bonding wire BW4, and the second end of the trace 24 is coupled to the amplifier 30. In other words, the system 100 is coupled to the amplifier 30 via the traces 22 and 24. The amplifier 30 may be for example a differential amplifier configured to transmit differential signals via the traces 22 and 24. The first end of the amplifier 30 is coupled to the second end of the bonding wire BW1 via the trace 22, and the second end of the amplifier 30 is coupled to the second end of the bonding wire BW4 via the trace 24. Furthermore, in the system 100 depicted in FIG. 1, the trace 22 is for example coupled to the bonding wire BW1 via the capacitor C1, and the trace 24 is for example coupled to the bonding wire BW4 via the capacitor C2. This way, by arranging the above-mentioned bonding wires and capacitors in a symmetric configuration, a first impedance from the second end of the trace 22 to the first end of the trace 22 may be equal to a second impedance from the second end of the trace 24 to the first end of the trace 24, thereby ensuring proper operation of the system 100 when applied to a structure using differential signaling. Moreover, the system 200 depicted in FIG. 2 may also be applied to a structure using differential signaling. The system 200 may also be coupled to the amplifier 30 via the traces 22 and 24. Furthermore, the radio frequency (RF) signals generated by the amplifier 30 may be received via the second ends of the bonding wires BW1, BW2, BW3 and BW4. In other words, the second ends of the bonding wires BW1, BW2, BW3 and BW4 may serve as input ends of the RF signals.

The system 200 depicted in FIG. 2 is similar to the system 100 depicted in FIG. 1, but the system 200 differs from the system 100 in the configuration of the bonding wire BW1 and the capacitor C1 in the first series combination. In the embodiment depicted in FIG. 2, the first end of the capacitor C1 is coupled to the first end of the primary coil L1, the second end of the capacitor C1 is coupled to the first end of the bonding wire BW1, and the second end of the bonding wire BW1 is coupled to the second end of the bonding wire BW2. This way, the capacitor C1 and the bonding wire BW1 in the first series combination together generate capacitive impedance which reduces inductive impedance generated by the bonding wire BW2. In some embodiments, the capacitive impedance generated by the capacitor C1 and the bonding wire BW1 in the first series combination together may compensate the inductive impedance generated by the bonding wire BW2. Regarding the arrangement of the bonding wire BW4 and the capacitor C2 in the second series combination, the first end of the capacitor C2 is coupled to the second end of the primary coil L1, the second end of the capacitor C2 is coupled to the first end of the bonding wire BW4, and the second end of the bonding wire BW4 is coupled to the second end of the bonding wire BW3 in the embodiment depicted in FIG. 2. This way, the capacitor C2 and the bonding wire BW4 in the second series combination together generate capacitive impedance which reduces inductive impedance generated by the bonding wire BW3. In some embodiments, the capacitive impedance generated by the capacitor C2 and the bonding wire BW4 in the second series combination together may compensate the inductive impedance generated by the bonding wire BW3.

On the other hand, in the system 200 depicted in FIG. 2, the first chip 10 may include four pads P1-P4 and the second chip 20 may include two pads Q1-Q2, wherein the first and second ends of the bonding wire BW1 are respectively connected to the pad P1 of the first chip 10 and the pad Q1 of the second chip 20, the first and second ends of the bonding wire BW2 are respectively connected to the pad P2 of the first chip 10 and the pad Q1 of the second chip 20, the first and second ends of the bonding wire BW3 are respectively connected to the pad P3 of the first chip 10 and the pad Q2 of the second chip 20, and the first and second ends of the bonding wire BW4 are respectively connected to the pad P4 of the first chip 10 and the pad Q2 of the second chip 20. In other words, the bonding wires BW1-BW4 are connected to the first chip 10 respectively via dedicated pads P1-P4, the bonding wires BW1 and BW2 are connected to the second chip 20 via the shared pad Q1, and the bonding wires BW3 and BW4 are connected to the second chip 20 via the shared pad Q2. In other embodiments, the bonding wires BW1 and BW2 may also be connected to the second chip 20 respectively via two dedicated pads which are coupled to each other via a trace instead of using the pad Q1 as a shared contact point. Similarly, the bonding wires BW3 and BW4 may also be connected to the second chip 20 respectively via two dedicated pads which are coupled to each other via a trace instead of using the pad Q2 as a shared contact point.

In the system 200 depicted in FIG. 2, the first chip 10 further include two pads O1-O2 as its output ends O1-O2. The first end of the primary coil L1 is coupled to the first end of the bonding wire BW1 via the pad P1 and coupled to the first end of the bonding wire BW2 via the pad P2, the second end of the primary coil L1 is coupled to the first end of the bonding wire BW3 via the pad P3 and coupled to the first end of the bonding wire BW4 via the pad P4, the first end of the secondary coil L2 is coupled to the pad O1, and the second end of the secondary coil L2 is coupled to the pad O2. Also, in the embodiment depicted in FIG. 2, the first end of the capacitor C1 is coupled to the pad P2 of the first chip 10 (i.e., the first end of the capacitor C1 may be coupled to the pad Q1 of the second chip 20 via the bonding wire BW2), the second end of the capacitor C1 is coupled to the pad P1 of the first chip 10 (i.e., the second end of the capacitor C1 may be coupled to the pad Q1 of the second chip 20 via the bonding wire BW1), the first end of the capacitor C2 is coupled to the pad P3 of the first chip 10 (i.e., the first end of the capacitor C2 may be coupled to the pad Q2 of the second chip 20 via the bonding wire BW3), the second end of the capacitor C2 is coupled to the pad P4 of the first chip 10 (i.e., the second end of the capacitor C2 may be coupled to the pad Q2 of the second chip 20 via the bonding wire BW4).

Compared to the system 100 depicted in FIG. 1, the systems 301-303 depicted in FIGS. 3A-3C and the systems 401-404 depicted in FIGS. 4A-4D differ from the system 100 in that the bonding wire BW2/the capacitor C1 and the bonding wire BW3/the capacitor C2 are arranged in a crossover manner. This way, the impedance matching of the systems 301-303 and 401-404 may be adjusted in order to meet a specific impedance requirement. Further elaboration will be provided hereafter. As depicted in FIGS. 3A-3C and 4A-4D, each of the systems 301-303 and 401-404 includes a primary coil L1, a secondary coil L2, a bonding wire BW1, a first series combination, a second series combination and a bonding wire BW4, wherein the first series combination includes a bonding wire BW2 and a capacitor C1 coupled in series, and the second series combination includes a bonding wire BW3 and a capacitor C2 coupled in series. The first end of the bonding wire BW1 is coupled to the first end of the primary coil L1, the first end of the first series combination is coupled to the first end of the primary coil L1, the first end of the second series combination is coupled to the second end of the primary coil L1, the second end of the second series combination is coupled to the second end of the bonding wire BW1, the first end of the bonding wire BW4 is coupled to the second end of the primary coil L1, the second end of the bonding wire BW4 is coupled to the second end of the first series combination, and the first end of the secondary coil L2 is coupled to an output end O1.

In the system 301 depicted in FIG. 3A, regarding the arrangement of the bonding wire BW2 and the capacitor C1 in the first series combination and the arrangement of the bonding wire BW3 and the capacitor C2 in the second series combination, the first end of the bonding wire BW2 is coupled to the first end of the primary coil L1, the second end of the bonding wire BW2 is coupled to the first end of the capacitor C1, the second end of the capacitor C1 is coupled to the second end of the bonding wire BW4, the first end of the bonding wire BW3 is coupled to the second end of the primary coil L1, the second end of the bonding wire BW3 is coupled to the first end of the capacitor C2, and the second end of the capacitor C2 is coupled to the second end of the bonding wire BW1, thereby resulting in a crossover configuration of the transmission lines.

Furthermore, in the system 301 depicted in FIG. 3A, the first end of the capacitor C1 is coupled to the pad Q2 of the second chip 20 (i.e., the first end of the capacitor C1 may be coupled to the pad P1 of the first chip 10 via the bonding wire BW2), the second end of the capacitor C1 is coupled to the pad Q4 of the second chip 20 (i.e., the second end of the capacitor C1 may be coupled to the pad P2 of the first chip 10 via the bonding wire BW4), the first end of the capacitor C2 is coupled to the pad Q3 of the second chip 20 (i.e., the first end of the capacitor C2 may be coupled to the pad P2 of the first chip 10 via the bonding wire BW3), and the second end of the capacitor C2 is coupled to the pad Q1 of the second chip 20 (i.e., the second end of the capacitor C2 may be coupled to the pad P1 of the first chip 10 via the bonding wire BW1). Meanwhile, in the second chip 20, the pads Q1 is coupled to the pad Q3 via the capacitor C2, and the pad Q2 is coupled to the pad Q4 via the capacitor C1.

In some embodiments, the system 301 depicted in FIG. 3A may be applied to a structure using differential signaling. Therefore, the system 301 may further include traces 22 and 24 which may be coupled to the load of the system 301. In the embodiment depicted in FIG. 3A, the load of the system 301 is for example the amplifier 30, the first end of the trace 22 is coupled to the second end of the bonding wire BW1, the second end of the trace 22 is coupled to the amplifier 30, the first end of the trace 24 is coupled to the second end of the bonding wire BW4, and the second end of the trace 24 is coupled to the amplifier 30. In other words, the system 301 is coupled to the amplifier 30 via the traces 22 and 24. The amplifier 30 may be for example a differential amplifier configured to transmit differential signals via the traces 22 and 24. The first end of the amplifier 30 is coupled to the second end of the bonding wire BW1 via the trace 22, and the second end of the amplifier 30 is coupled to the second end of the bonding wire BW4 via the trace 24. This way, by arranging the above-mentioned bonding wires and capacitors in a symmetric configuration, a first impedance from the second end of the trace 22 to the first end of the trace 22 may be equal to a second impedance from the second end of the trace 24 to the first end of the trace 24, thereby ensuring proper operation of the system 301 when applied to a structure using differential signaling. Moreover, the systems 302-303 depicted in FIGS. 3B-3C and the systems 401-404 depicted in FIGS. 4A-4D may also be applied to a structure using differential signaling. The system 302, 303 and 401-404 may also be coupled to the amplifier 30 via the traces 22 and 24. Furthermore, the RF signals generated by the amplifier 30 may be received via the second ends of the bonding wires BW1, BW2, BW3 and BW4. In other words, the second end of the bonding wires BW1, BW2, BW3 and BW4 may serve as input ends of the RF signals.

The system 302 depicted in FIG. 3B is similar to the system 301 depicted in FIG. 3A, but the system 302 further includes a switch SW1 and a switch SW2. The switch SW1 is coupled in series to the capacitor C1, and the switch SW2 is coupled in series to the capacitor C2. The turn-on degree of the switch SW1 and the turn-on degree of the switch SW2 may thus be adjusted, thereby varying the impedance of the system 302. In the system 302 depicted in FIG. 3B, the capacitor C1 is coupled in series between the bonding wire BW3 and the switch SW1, and the capacitor C2 is coupled in series between the bonding wire BW3 and the switch SW2. Furthermore, in the system 302 depicted in FIG. 3B, the first end of the capacitor C1 is coupled to the pad Q2 of the second chip 20 (i.e., the first end of the capacitor C1 may be coupled to the pad P1 of the first chip 10 via the bonding wire BW2), the second end of the capacitor C1 is coupled to the pad Q4 of the second chip 20 via the switch SW1 (i.e., the second end of the capacitor C1 may be coupled to the pad P2 of the first chip 10 via the switch SW1 and the bonding wire BW4), the first end of the capacitor C2 is coupled to the pad Q3 of the second chip 20 (i.e., the first end of the capacitor C2 may be coupled to the pad P2 of the first chip 10 via the bonding wire BW3), and the second end of the capacitor C2 is coupled to the pad Q1 of the second chip 20 via the switch SW2 (i.e., the second end of the capacitor C2 may be coupled to the pad P1 of the first chip 10 via the switch SW2 and the bonding wire BW1). Also, in the second chip 20, the pad Q1 is coupled to the pad Q3 via the switch SW2 and the capacitor C2, and the pad Q2 is coupled to the pad Q4 via the capacitor C1 and the switch SW1.

The system 303 depicted in FIG. 3C is similar to the system 302 depicted in FIG. 3B, but the system 303 differs from the system 302 in that the locations of the switch SW1 and the capacitor C1 are interchanged and that the locations of the switch SW2 and the capacitor C2 are interchanged. In other words, in the system 303 depicted in FIG. 3C, the switch SW1 is coupled in series between the bonding wire BW2 and the capacitor C1, and the switch SW2 is coupled in series between the bonding wire BW3 and the capacitor C2. Furthermore, in the system 303 depicted in FIG. 3C, the first end of the capacitor C1 is coupled to the pad Q2 of the second chip 20 via the switch SW1 (i.e., the first end of the capacitor C1 may be coupled to the pad P1 of the first chip 10 via the switch SW1 and the bonding wire BW2), the second end of the capacitor C1 is coupled to the pad Q4 of the second chip 20 (i.e., the second end of the capacitor C1 may be coupled to the pad P2 of the first chip 10 via the bonding wire BW4), the first end of the capacitor C2 is coupled to the pad Q3 of the second chip 20 via the switch SW2 (i.e., the first end of the capacitor C2 may be coupled to the pad P2 of the first chip 10 via the switch SW2 and the bonding wire BW3), and the second end of the capacitor C2 is coupled to the pad Q1 of the second chip 20 (i.e., the second end of the capacitor C2 may be coupled to the pad P1 of the first chip 10 via the bonding wire BW1). Also, in the second chip 20, the pas Q1 is coupled to the pad Q3 via the capacitor C2 and the switch SW2, and the pad Q2 is coupled to the pad Q4 via the switch SW1 and the capacitor C1.

The system 401 depicted in FIG. 4A is similar to the system 301 depicted in FIG. 3A, but the system 401 differs from the system 301 in the configuration of the bonding wire BW2 and the capacitor C1 in the first series combination and in the configuration of the bonding wire BW3 and the capacitor C2 in the second series combination. In the system 401 depicted in FIG. 4A, the first end of the capacitor C1 is coupled to the first end of the primary coil L1, the second end of the capacitor C1 is coupled to the first end of bonding wire BW2, the second end of the bonding wire BW2 is coupled to the second end of the bonding wire BW4, the first end of the capacitor C2 is coupled to the second end of the primary coil L1, the second end of the capacitor C2 is coupled to the first end of the bonding wire BW3, and the second end of the bonding wire BW3 is coupled to the second end of the bonding wire BW1, thereby resulting in a crossover configuration of the transmission lines.

Furthermore, in the system 401 depicted in FIG. 4A, the first end of the capacitor C1 is coupled to the pad P1 of the first chip 10 (i.e., the first end of the capacitor C1 may be coupled to the pad Q1 of the second chip 20 via the bonding wire BW1), the second end of the capacitor C1 is coupled to the pad P2 of the first chip 10 (i.e., the second end of the capacitor C1 may be coupled to the pad Q2 of the second chip 20 via the bonding wire BW2), the first end of the capacitor C2 is coupled to the pad P4 of the first chip 10 (i.e., the first end of the capacitor C2 may be coupled to the pad Q4 of the second chip 20 via the bonding wire BW4), the second end of the capacitor C2 is coupled to the pad P3 of the first chip 10 (i.e., the second end of the capacitor C2 may be coupled to the pad Q3 of the second chip 20 via the bonding wire BW1). Also, in the second chip 20, the pads Q1 and Q3 are coupled to each other, and the pads Q2 and Q4 are coupled to each other.

The system 402 depicted in FIG. 4B is similar to the system 401 depicted in FIG. 4A, but the system 402 further includes a switch SW1 and a switch SW2. The switch SW1 is coupled in series to the capacitor C1, and the switch SW2 is coupled in series to the capacitor. The turn-on degree of the switch SW1 and the turn-on degree of the switch SW2 may thus be adjusted for varying the impedance of the system 402. In the system 402 depicted in FIG. 4B, the capacitor C1 is coupled in series between the bonding wire BW2 and the switch SW1, and the capacitor C2 is coupled in series between the bonding wire BW3 and the switch SW2. Furthermore, in the system 402 depicted in FIG. 2, the first end of the capacitor C1 is coupled to the pad P1 of the first chip 10 via the switch SW1 (i.e., the first end of the capacitor C1 may be coupled to the pad Q1 of the second chip 20 via the switch SW1 and the bonding wire BW1), the second end of the capacitor C1 is coupled to the pad P2 of the first chip 10 (i.e., the second end of the capacitor C1 may be coupled to the pad Q2 of the second chip 20 via the bonding wire BW2), the first end of the capacitor C2 is coupled to the pad P4 of the first chip 10 via the switch SW2 (i.e., the first end of the capacitor C2 may be coupled to the pad Q4 of the second chip 20 via the switch SW2 and the bonding wire BW4), the second end of the capacitor C2 is coupled to the pad P3 of the first chip 10 (i.e., the second end of the capacitor C2 may be coupled to the pad Q3 of the second chip 20 via the bonding wire BW3). Also, in the second chip 20, the pads Q1 and Q3 are coupled to each other, and the pads Q2 and Q4 are coupled to each other.

The system 403 depicted in FIG. 4C is similar to the system 402 depicted in FIG. 4B, but the system 403 differs from the system 402 in that the locations of the switch SW1 and the capacitor C1 are interchanged and that the locations of the switch SW2 and the capacitor C2 are interchanged. In other words, in the system 403 depicted in FIG. 4C, the switch SW1 is coupled in series between the bonding wire BW2 and the capacitor C1, and the switch SW2 is coupled in series between the bonding wire BW3 and the capacitor C2. Furthermore, in the system 403 depicted in FIG. 4C, the first end of the capacitor C1 is coupled to the pad P1 of the first chip 10 (i.e., the first end of the capacitor C1 may be coupled to the pad Q1 of the second chip 20 via the bonding wire BW1), the second end of the capacitor C1 is coupled to the pad P2 of the first chip 10 via the switch SW1 (i.e., the second end of the capacitor C1 may be coupled to the pad Q2 of the second chip 20 via the switch SW1 and the bonding wire BW2), the first end of the capacitor C2 is coupled to the pad P4 of the first chip 10 (i.e., the first end of the capacitor C2 may be coupled to the pad Q4 of the second chip 20 via the bonding wire BW4), the second end of the capacitor C2 is coupled to the pad P3 of the first chip 10 via the switch SW2 (i.e., the second end of the capacitor C2 may be coupled to the pad Q3 of the second chip 20 via the switch SW2 and the bonding wire BW3). Also, in the second chip 20, the pads Q1 and Q3 are coupled to each other, and the pads Q2 and Q4 are coupled to each other.

The system 404 depicted in FIG. 4D is similar to the system 401 depicted in FIG. 4A, but the system 404 further includes a switch SW1 and a switch SW2. The first end of the switch SW1 is coupled to the second end of the bonding wire BW1, the second end of the switch SW1 is coupled to the second end of the bonding wire BW3, the first end of the switch SW2 is coupled to the second end of the bonding wire BW4, and the second end of the switch SW2 is coupled to the second end of the bonding wire BW2. The turn-on degree of the switch SW1 and the turn-on degree of the switch SW2 may thus be adjusted for varying the impedance of the system 404. Furthermore, in the system 404 depicted in FIG. 4D, the first end of the capacitor C1 is coupled to the pad P1 of the first chip 10 (i.e., the first end of the capacitor C1 may be coupled to the pad Q1 of the second chip 20 via the bonding wire BW1), the second end of the capacitor C1 is coupled to the pad P2 of the first chip 10 (i.e., the second end of the capacitor C1 may be coupled to the pad Q2 of the second chip 20 via the bonding wire BW2), the first end of the capacitor C2 is coupled to the pad P4 of the first chip 10 (i.e., the first end of the capacitor C2 may be coupled to the pad Q4 of the second chip 20 via the bonding wire BW4), and the second end of the capacitor C2 is coupled to the pad P3 of the first chip 10 (i.e., the second end of the capacitor C2 may be coupled to the pad Q3 of the second chip 20 via the bonding wire BW3). Also, in the second chip 20, the pad Q1 is coupled to the pad Q3 via the switch SW1, and the pad Q2 is coupled to the pad Q4 via the switch SW2.

In the systems 302-303 depicted in FIGS. 3B-3C and the systems 402-404 depicted in FIGS. 4B-4D, the structure on the first end of the primary coil L1 is symmetric to the structure on the second end of the primary coil L1. Also, when the systems 302-303 depicted in FIGS. 3B-3C and the systems 402-404 depicted in FIGS. 4B-4D are applied to a structure using differential signaling, the turn-on degree of the switch SW1 is equal to the turn-on degree of the switch SW2 is equal in an operational mode. Furthermore, a first impedance from the second end of the trace 22 to the first end of the trace 22 and a second impedance from the second end of the trace 22 to the first end of the trace 24 may be varied by adjusting the turn-on degrees of the switches SW1 and SW2. This way, by operating the switches SW1 and SW2 with the same turn-on degree, the first impedance may be equal to the second impedance, thereby ensuring proper operation of the systems 302-303 and 402-404 when applied to a structure using differential signaling.

In the embodiments depicted in FIGS. 1, 2, 3A-3C and 4A-4D, the bonding wires BW1-BW4 are respectively bond-wired between the first chip 10 and the second chip 20 so that the transformer TR is able to communicate with the amplifier 30. In other embodiments of the present invention when the first chip 10 and the second chip 20 are disposed on the same circuit board, the bonding wires BW1-BW4 depicted in the embodiments of FIGS. 1, 2, 3A-3C and 4A-4D may be replaced by different kind of conducting wires (such as traces) for providing signal transmission paths between the first chip 10 and the second chip 20.

In conclusion, the present invention provides a first signal transmission path between two chips in the system via a series combination which includes a first bonding wire/trace and a capacitor, and provides a second signal transmission path between the two chips via a second bonding wire/trace. This way, the capacitive impedance of the first signal transmission path may reduce the inductive impedance of the second signal transmission path, thereby achieving impedance matching. In addition, the bonding wire/trace and the capacitor may be arranged in a crossover manner, thereby adjusting the impedance matching of the system for meeting a specific impedance requirement.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system, comprising:
a primary coil including a first end and a second end;
a first series combination comprising a first conducting wire and a first capacitor coupled in series, wherein a first end of the first series combination is coupled to the first end of the primary coil;
a second conducting wire, wherein a first end of the second conducting wire is coupled to the first end of the primary coil, and a second end of the second conducting wire is coupled to a second end of the first series combination; and
a secondary coil including a first end and a second end, wherein the first end of the secondary coil is coupled to an output end.

2. The system of claim 1, wherein:
a first end of the first conducting wire is coupled to the first end of the primary coil, a second end of the first conducting wire is coupled to a first end of the first capacitor, and a second end of the first capacitor is coupled to the second end of the second conducting wire; or
the first end of the first conductor is coupled to the first end of the primary coil, the second end of the first conductor is coupled to the first end of the first conducting wire, and the second end of the first conducting wire is coupled to the second end of the second conducting wire.

3. The system of claim 1, further comprising:
a third conducting wire, wherein a first end of the third conducting wire is coupled to the second end of the primary coil; and
a second series combination comprising a fourth conducting wire and a second capacitor coupled in series, wherein a first end of the second series combination is coupled to the second end of the primary coil, and a second end of the second series combination is coupled to a second end of the third conducting wire.

4. The system of claim 3, wherein:
a first end of the fourth conducting wire is coupled to the second end of the primary coil, a second end of the fourth conducting wire is coupled to a first end of the second capacitor, and a second end of the second capacitor is coupled to the second end of the third conducting wire; or
the first end of the second conductor is coupled to the second end of the primary coil, the second end of the second conductor is coupled to the first end of the fourth conducting wire, and the second end of the fourth conducting wire is coupled to the second end of the third conducting wire.

5. The system of claim 1, wherein the primary coil comprises a center tap coupled to a power voltage.

6. The system of claim 1, wherein the second conducting wire generates an inductive impedance, and the first conducting wire and the first capacitor together generate a capacitive impedance which reduces the inductive impedance.

7. The system of claim 1, wherein:
the first conducting wire is a first bonding wire which is wire-bonded between a first chip and a second chip;
a first pad is disposed on the first chip and connected to a first end of the first bonding wire;
a second pad is disposed on the second chip and connected to a second end of the first bonding wire; and
the second conducting wire is a second bonding wire which is wire-bonded between the first chip and the second chip.

8. The system of claim 1, wherein:
the first conducting wire is a first trace; and
the second conducting wire is a second trace.

9. A system, comprising:
a primary coil including a first end and a second end;
a first bonding wire including a first end coupled to the first end of the primary coil;
a first series combination comprising a second bonding wire and a first capacitor coupled in series, wherein a first end of the first series combination is coupled to the first end of the primary coil;
a second series combination comprising a third bonding wire and a second capacitor coupled in series, wherein a first end of the second series combination is coupled to the second end of the primary coil, and a second end of the second series combination is coupled to a second end of the first bonding wire;
a fourth bonding wire including a first end coupled to the second end of the primary coil and a second end coupled to the second end of the first series combination; and
a secondary coil including a first end and a second end, wherein the first end of the secondary coil is coupled to an output end.

10. The system of claim 9, wherein:
a first end of the second bonding wire is coupled to the first end of the primary coil, a second end of the second bonding wire is coupled to a first end of the first capacitor, a second end of the first capacitor is coupled to the second end of the fourth bonding wire, a first end of the third bonding wire is coupled to the second end of the primary coil, a second end of the second bonding wire is coupled to a first end of the second capacitor, and a second end of the second capacitor is coupled to the second end of the first bonding wire; or
the first end of the first capacitor is coupled to the first end of the primary coil, the second end of the first capacitor is coupled to the first end of the second bonding wire, the second end of the second bonding wire is coupled to the second end of the fourth bonding wire, the first end of the second capacitor is coupled to the second end of the primary coil, the second end of the second capacitor is coupled to the first end of the third bonding wire, and the second end of the third bonding wire is coupled to the second end of the first bonding wire.

11. The system of claim 10, further comprising:
a first switch coupled in series to the first capacitor; and;
a second switch coupled in series to the second capacitor.

12. The system of claim 11, wherein a first turn-on degree of the first switch is equal to a second turn-on degree of the second switch in an operational mode.

13. The system of claim 11, further comprising:
a first trace including a first end coupled to the second end of the first bonding wire and a second end coupled to an amplifier; and
a second trace including a first end coupled to the second end of the fourth bonding wire and a second end coupled to the amplifier, wherein:
a first impedance from the second end of the first trace to the first end of the first trace varies with a first turn-on degree of the first switch and a second turn-on degree of the second switch in an operational mode; and
a second impedance from the second end of the second trace to the first end of the second trace varies with the first turn-on degree of the first switch and the second turn-on degree of the second switch in the operational mode.

14. The system of claim 13, wherein the first impedance is equal to the second impedance.

15. The system of claim 9, further comprising:
a first switch including a first end coupled to the second end of the first bonding wire and a second end coupled to a second end of the third bonding wire; and;
a second switch including a first end coupled to the second end of the fourth bonding wire and a second end coupled to the second end of the second bonding wire, wherein:
a first end of the first capacitor is coupled to the first end of the primary coil;
a second end of the first capacitor is coupled to the first end of the second bonding wire;
the second end of the second bonding wire is coupled to the second end of the fourth bonding wire;
a first end of the second capacitor is coupled to the second end of the primary coil;
a second end of the second capacitor is coupled to a first end of the third bonding wire; and
the second end of the third bonding wire is coupled to the second end of the first bonding wire.

16. The system of claim 15, wherein a first turn-on degree of the first switch is equal to a second turn-on degree of the second switch in an operational mode.

17. The system of claim 15, further comprising:
a first trace including a first end coupled to the second end of the first bonding wire and a second end coupled to an amplifier; and
a second trace including a first end coupled to the second end of the fourth bonding wire and a second end coupled to the amplifier, wherein:
a first impedance from the second end of the first trace to the first end of the first trace varies with a first turn-on degree of the first switch and a second turn-on degree of the second switch in an operational mode; and
a second impedance from the second end of the second trace to the first end of the second trace varies with the first turn-on degree of the first switch and the second turn-on degree of the second switch in the operational mode.

18. The system of claim 17, wherein the first impedance is equal to the second impedance.

19. The system of claim 9, wherein the first bonding wire, the second bonding wire, the third bonding wire, the fourth bonding wire are wire-bonded between a first chip and a second chip respectively.

20. A system, comprising:
a primary coil including a first end and a second end;
a first trace including a first end coupled to the first end of the primary coil;
a first series combination comprising a second trace and a first capacitor coupled in series, wherein a first end of the first series combination is coupled to the first end of the primary coil;
a second series combination comprising a third trace and a second capacitor coupled in series, wherein a first end of the second series combination is coupled to the second end of the primary coil, and a second end of the second series combination is coupled to a second end of the first trace;
a fourth trace including a first end coupled to the second end of the primary coil and a second end coupled to the second end of the first series combination; and
a secondary coil including a first end and a second end, wherein the first end of the secondary coil is coupled to an output end.
